(19) United States
(12) Patent Application Publication
(10) Pub. No.: US 2015/0333246 A1
(43) Pub. Date: Nov. 19, 2015

(54) HEAT CONVERSION DEVICE

(71) Applicant: LG INNOTEK CO., LTD., Seoul (KR)

(72) Inventors: Jong Min Lee, Seoul (KR); Sang Gon Kim, Seoul (KR); Sook Hyun Kim, Seoul (KR); Chae Hoon Kim, Seoul (KR); Myoung Lae Roh, Seoul (KR); Joong Hyun Park, Seoul (KR); Hyung Min Sohn, Seoul (KR); Jong Bae Shin, Seoul (KR); Boone Won, Seoul (KR); Yong Sang Cho, Seoul (KR); Yun Kyoung Jo, Seoul (KR)

(21) Appl. No.: 14/710,946

(22) Filed: May 13, 2015

(30) Foreign Application Priority Data
May 13, 2014 (KR) 10-2014-0057406

(51) Int. Cl. H01L 35/32; H01L 35/30

(52) U.S. Cl. CPC H01L 35/32; H01L 35/30

(57) ABSTRACT

Provided is a heat conversion device, including: a unit thermoelectric module including a first semiconductor element and a second semiconductor element; and a heat conversion module performing heat conversion by coming into contact with the unit thermoelectric module, wherein the heat conversion module includes: a heat conversion substrate coming into direct contact with at least any one of one end and the other end of the first semiconductor element or the second semiconductor element; and a radiating unit disposed on the heat conversion substrate.

### CROSS-REFERENCE TO RELATED APPLICATION

This application claims the benefit under 35 U.S.C. §119 to Korean Patent Application No. 10-2014-0057406, filed May 13, 2014, which is hereby incorporated by reference in its entirety.

### BACKGROUND

1. Field of the Invention

Embodiments of the present invention relate to a heat conversion device including a thermoelectric element.

2. Description of the Related Arts

Generally, a thermoelectric element including a thermoelectric conversion element is configured such that a P-type thermoelectric material and an N-type thermoelectric material are bonded between metal electrodes to form a PN bonding pair. When a temperature difference is applied to the PN bonding pair, electric power is produced by a Seebeck effect so that the thermoelectric element can serve as a power generation device. Furthermore, the thermoelectric element may be used as a temperature control device by the Peltier effect that one of the PN boding pair is cooled and another one thereof is heated.

With regard to the thermoelectric element applied to a temperature controlling device, the thermoelectric element is disposed between the pair of substrates, and a surface of the heat sink member in contact with the surface of the substrate is adhered to the surface of the substrate using a heterojunction material, such as a thermal interface material (TIM) having an adhesive property. This thermal interface material may be, for example, radiating grease. Due to presence of this thermal interface material, it is problematic in that heat transmission efficiency of the thermoelectric semiconductor element for implementing a heat absorbing and emitting operation is reduced, thereby causing heat loss.

### BRIEF SUMMARY

The present invention has been made keeping in mind the above problems, and an aspect of embodiments of the present invention provides a heat conversion device in which an electrode pattern is formed on a surface of a heat sink structure to come into direct contact with a thermoelectric element without a substrate member forming a thermoelectric module between a thermoelectric semiconductor element and the heat sink structure, so that heat loss due to presence of a thermal interface material can be prevented, and heat efficiency can be improved.

According to an aspect of the embodiments of the present invention, a heat conversion device may include: at least one unit thermoelectric module including a first semiconductor element and a second semiconductor element; and at least one heat conversion module performing heat conversion by coming into contact with the unit thermoelectric module, wherein the heat conversion module includes: a heat conversion substrate coming into direct contact with at least any one of one end and the other end of the first semiconductor element or the second semiconductor element; and a radiating unit disposed on the heat conversion substrate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a conceptual view of a heat conversion device according to one embodiment of the present invention;

FIG. 2 is a view illustrating an example in which electrode patterns are implemented on heat conversion substrates of the heat conversion device;

FIG. 3 is a cross-sectional view of the subject matter illustrating a contact structure of a first semiconductor element, a second semiconductor element, and the heat conversion substrates of a heat conversion module.

FIG. 4 is an exemplary view illustrating a contact structure of and a plurality of thermoelectric semiconductor elements, and electrode patterns directly patterned on the heat conversion substrates;

FIG. 5 illustrates a conceptual view of a heat conversion device according to the other embodiment of the present invention;

FIGS. 6 and 7 are exemplary views of a heat conversion member of FIG. 5; and

FIG. 8 shows an application example of the heat conversion device according to the other embodiment of the present invention.

### DETAILED DESCRIPTION

Hereinafter, the configurations and operations according to embodiments of the present invention will be described in detail with reference to the accompanying drawings. The present invention may, however, be embodied in different forms and should not be construed as limited to the embodiments set forth herein. In the explanation with reference to the accompanying drawings, regardless of reference numerals of the drawings, like numbers refer to like elements through the specification, and repeated explanation thereon is omitted. Terms such as a first term and a second term may be used for explaining various constitutive elements, but the constitutive elements should not be limited to these terms. These terms are only used for the purpose for distinguishing a constitutive element from other constitutive element. As used herein, the singular forms “a,” “an” and “the” are intended to include the plural forms as well, unless the context clearly indicates otherwise.

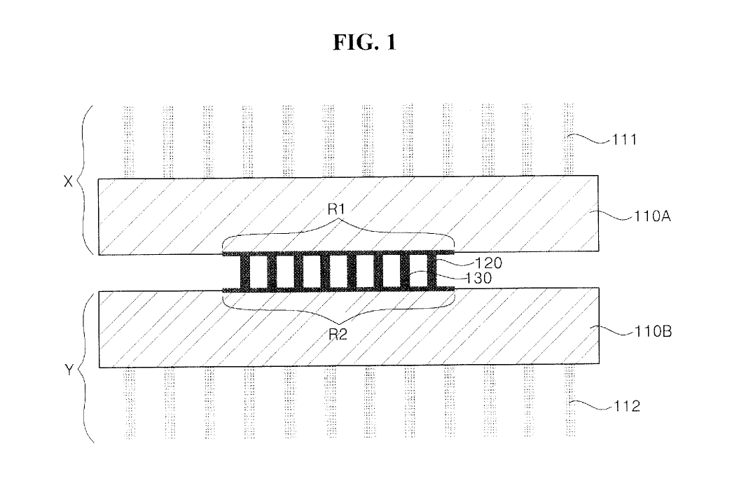

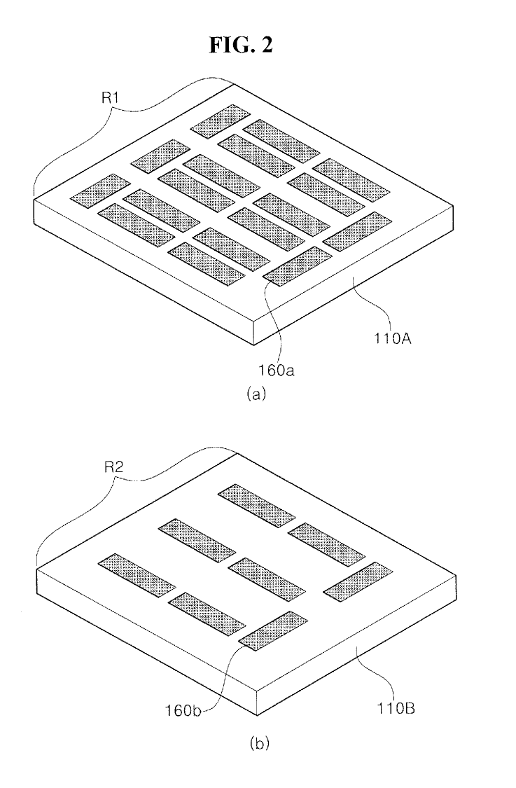

FIG. 1 is a conceptual view of a heat conversion device according to one embodiment of the present invention, and FIG. 2 is a view showing an example in which electrode patterns are implemented on a heat conversion substrate of the heat conversion device of FIG. 1.

Referring to FIGS. 1 and 2, the heat conversion device according to the one embodiment of the present invention includes at least one unit thermoelectric module Z including a first semiconductor element 120 and a second semiconductor element 130. Furthermore, the heat conversion device may be configured to include heat conversion modules X, Y performing heat conversion by coming into contact with the unit thermoelectric module Z.

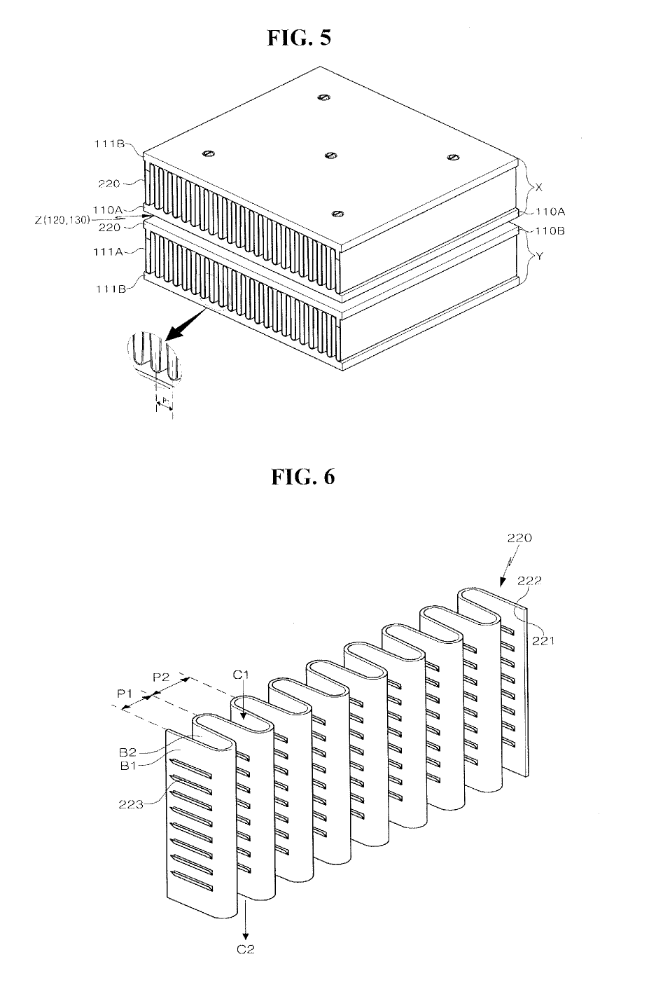

In such a case, the heat conversion modules X, Y may be configured such that radiating units 111, 112 in various forms are disposed on heat conversion substrates 110A, 110B, respectively. The radiating units 111, 112 have a structure in which a pin structure-like shape is implemented, but are not limited thereto. Structures as shown in FIG. 5 or 6 may be disposed.

In particular, at least one of one end and the other end of the first semiconductor element 120 and the second semiconductor element 130 may be implemented to come into direct contact with one surface of each heat conversion substrate 110A, 110B of the heat conversion modules.

That is, the heat conversion device according to the one embodiment of the present invention may be implemented such that the electrode patterns constituting an electrical connection between the semiconductor elements constituting the thermoelectric module are formed on a surface of a radiating structure rather than being formed on a separate substrate member. Thanks to this configuration, the substrate can be removed from the existing thermoelectric module.

As one example, as illustrated in FIG. 1, the electrode patterns are directly formed on one surface of each heat conversion substrate 110A, 110A of the heat conversion modules, and the first semiconductor element 120 and the second semiconductor element 130 come into contact with the electrode patterns so that an electrical connection can be implemented.

The first semiconductor element 120 and the second semiconductor element 130 come into contact with the electrode patterns formed on each external surface (heat conversion substrates) of the heat conversion modules and are disposed to be electrically connected to each other. The thermoelectric semiconductor element is configured such that a P-type semiconductor and an N-type semiconductor are disposed to make a pair. When current is applied, a heat absorbing part and a heat emitting part are implemented on the pair of substrates by the Peltier effect.

Such a structure is implemented in a structure in which such that the electrode patterns are directly formed on the surface of the thermoelectric module (or device) implementing heat conversion of heat emitting and heat absorbing, and the thermoelectric semiconductor element comes into contact with the electrode patterns, rather than being implemented in a structure in which the pair of substrates are separately provided, the electrode patterns for an electrical connection between the semiconductor elements are implemented, and the thermoelectric semiconductor element is disposed between the pair of substrates. Thus, heat loss due to the presence of an adhesive material for bonding the separate structures can be prevented, and inefficiency of heat transmission generated due to addition of the substrates can be improved.

Specifically, as illustrated in FIG. 1, the thermoelectric module including the first semiconductor element 120 and the second semiconductor element 130 may be configured to come in direct contact with the electrode patterns formed one surface of each heat conversion substrate 110A, 110B of the thermoelectric modules X, Y targeted for heat absorption and heat emission.

In the structure illustrated in FIG. 1, the heat conversion substrates 110A, 110B are disposed in both directions of one end and the other end of the first semiconductor element 120 and the semiconductor element 130 without being limited thereto. The heat conversion substrates may be disposed only at any one of the one end and the other end.

Moreover, as illustrated, the protruding structures 111, 112 are disposed on each surface opposite to each surface of the heat conversion substrates 110A, 110B to which the first semiconductor element 120 and the second semiconductor element 130 are connected, so that a heat emitting function and a heat absorbing function can be maximized. The protruding structures may be pin structures having a protruding column-like shape, and structures having curvature patterns which will be described later may be disposed.

FIG. 2 is an enlarged view illustrating only electrode pattern regions R1, R2 of the heat conversion substrates 110A, 110B to which the first semiconductor element 120 and the second semiconductor element 130 are connected.

As illustrated in FIG. 2, electrode patterns 160a, 160b are directly patterned on each surface of the heat conversion substrates 110A, 110B. Also, the first semiconductor element 120 and the second semiconductor element 130 previously described in the sections regarding FIG. 1 come into contact with and are connected to the electrode patterns 160a, 160b. In this case, the electrode patterns 160a, 160b may be formed on each surface of the heat conversion substrates 110A, 110B. Furthermore, by forming fixed grooves in the respective surfaces of the heat conversion substrates 110A, 110B, the electrode patterns may be formed to be partially embedded. This embedded structure may enable the electrode patterns to be stably mounted.

In the conventional structure of the thermoelectric module, the thermoelectric module is configured such that the first semiconductor element 120 and the second semiconductor element 130 are disposed between a pair of substrates having electrode patterns, and the electrode patterns are formed on an external surface of the thermoelectric module for which temperature control is required, and come into direct contact with the first semiconductor element 120 and the second semiconductor element 130. Thus, a thickness of the device can become thinner, efficiency of direct heat transmission can be increased, and heat loss can be prevented because a heterojunction material for bonding the substrate and the thermoelectric module, such as radiating grease and the like, is not used.

In particular, according to the one embodiment of the present invention, when the thermoelectric semiconductor elements are formed to come into direct contact with each external surface of the heat conversion modules, comparing it with the case in which contact (using an adhesive material such as a thermal grease) is performed using separate substrates, heat loss can be prevented and the performance of the thermoelectric element can be increased by 2 to 5% compared to performance of the existing thermoelectric element (Qc, ΔT).

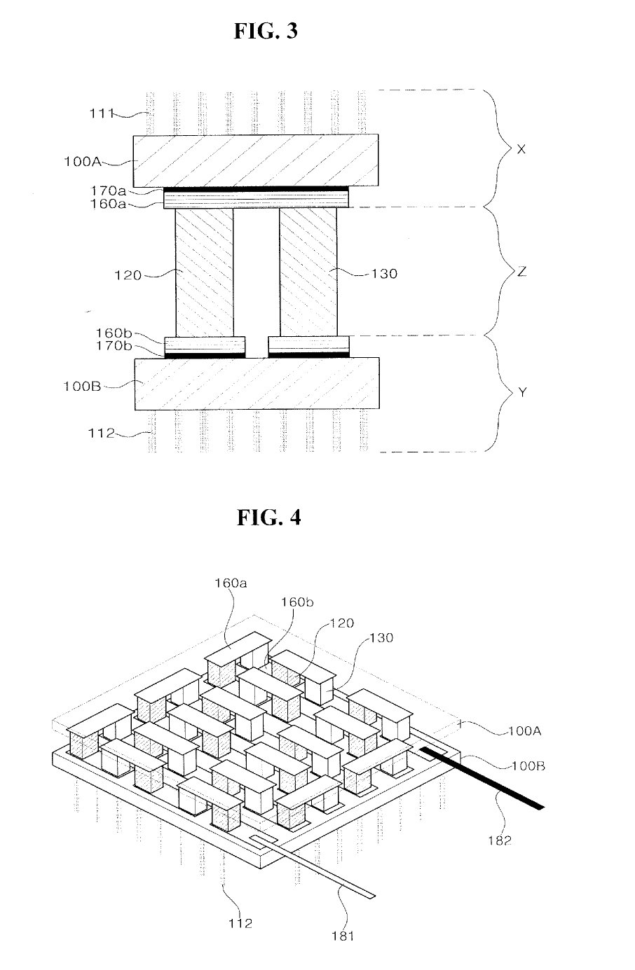

FIG. 3 is a cross-sectional view of a main part illustrating a contact structure of the first semiconductor element 120 and the second semiconductor element 130 described in the sections regarding FIG. 1, and the heat conversion substrates 110A, 110B of the heat conversion module.

As illustrated in FIG. 3, the first semiconductor element 120 and the second semiconductor element 130 come into contact with the electrode patterns 160a, 160a directly patterned on each surface of the heat conversion substrate 110A, 110B of the thermoelectric module without a separate structure, thereby implementing an electrical connection.

In such a case, when the heat conversion substrates 110A, 110B are made of a conductive metal material such as aluminum and the like, as illustrated in FIG. 3, separate insulating layers 170a, 170b may be disposed between the heat conversion substrate 110A and the electrode pattern 160a, and between the heat conversion substrate 110B and the electrode pattern 160b, respectively. Of course, when the heat conversion substrates are non-conductive, metal electrode patterns, which are directly patterned even without an insulating layer, are formed so as to be connected to the first semiconductor element 120 and the second semiconductor element 130.

Also, considering heat conductivity of the cooling thermoelectric module as a dielectric material having radiating performance, the insulating layers 170a, 170b may be made of a material having a heat conductivity of 5 to 10 W/K and may be formed in a thickness ranging from 0.01 mm to 0.15 mm. In this case, when the thickness of the insulating layer is less than 0.01 mm, insulating efficiency (or a withstanding voltage property) is largely reduced, and when the thickness is more than 0.15 mm, heat conductivity is reduced, thereby causing a reduction of radiating efficiency.

The electrode patterns 160a, 160b electrically connect the first semiconductor element and the second semiconductor element using an electrode material such as Cu, Ag, Ni, and the like. When the illustrated unit cells are connected, the electrode patterns form an electrical connection with the adjacent unit cells as illustrated in FIG. 4. A thickness of the electrode pattern may range from 0.01 to 0.3 mm.

When the thickness of the electrode pattern is less than 0.01 mm, a function of the electrode pattern as an electrode is reduced, thereby causing a reduction of electric conductivity. Also, when the thickness of the electrode pattern is more than 0.3 mm, electric conductivity is also reduced due to an increase of resistance.

In particular, with regard to the thermoelectric elements forming unit cells, thermoelectric elements including unit elements having a laminated structure according to the one embodiment of the present invention may be applied. In this case, one surface of the thermoelectric element may be composed of a P-type semiconductor as the first semiconductor element 120 and an N-type semiconductor as the second semiconductor element 130. The first semiconductor and the second semiconductor are connected to the metal electrodes 160a, 160b. Such a structure is formed in plural number, and the Peltier effect is implemented by circuit lines 181, 182 for supplying electric current to the semiconductor element by means of the electrodes.

A P-type semiconductor or N-type semiconductor material may be applied to the semiconductor elements in the thermoelectric module. With regard to the P-type semiconductor or the N-type semiconductor material, the N-type semiconductor element may be formed using a mixture in which a main raw material based on BiTe containing Se, Ni, Al, Cu, Ag, Pb, B, Ga, Te, Bi, and In is mixed with 0.001 to 1.0 wt % of Bi or Te based on a total weight of the main raw material. For example, when the main raw material is a Bi—Se—Te based material, Bi or Te may be added in an amount of 0.001 to 1.0 wt % based on the total weight of the Bi—Se—Te material. That is, when the Bi—Se—Te based material is added in an amount of 100 g, the amount of Bi or Te additionally mixed therewith may range from 0.001 to 1.0 g. As described above, when the amount of the material added to the main raw material ranges from 0.001 to 0.1 wt %, heat conductivity is not reduced, and electric conductivity is reduced. Thus, the numerical range has a meaning in that the increase of a ZT value cannot be expected.

The P-type semiconductor element may be formed using a mixture in which a main raw material based on BiTe containing Sb, Ni, Al, Cu, Ag, Pb, B, Ga, Te, Bi, and In is mixed with 0.001 to 1.0 wt % of Bi or Te based on a total weight of the main raw material. For example, when the main raw material is a Bi—Se—Te based material, Bi or Te may be added in an amount of 0.001 to 1.0 wt % based on the total weight of the Bi—Se—Te material. That is, when the Bi—Se—Te based material is added in an amount of 100 g, the amount of Bi or Te additionally mixed therewith may range from 0.001 to 1.0 g. As described above, when the amount of the material added to the main raw material ranges from 0.001 to 0.1 wt %, heat conductivity is not reduced, and electric conductivity is reduced. Thus, the numerical range has a meaning in that the increase of a ZT value cannot be expected.

The first semiconductor element and the second semiconductor element facing each other while forming unit cells may have the same shape and size. However, in this case, since electric conductivity of the P-type semiconductor element is different from that of the n-type semiconductor element, cooling efficiency is reduced. In consideration of this fact, any one of them may be formed to have a volume different from that of the other semiconductor element so that a cooling ability can be improved.

That is, the volumes of the semiconductor elements of the unit cells disposed to face each other may be formed different from each other in such a manner that the semiconductor elements are entirely formed to have different shapes, a cross section of any one of the semiconductor elements having the same height is formed to have a diameter wider than that of a cross section of another one, or the semiconductor elements having the same shape are formed to have different heights and different diameters of each cross section. In particular, a diameter of the N-type semiconductor element is formed larger than that of the P-type semiconductor element in order to cause the increase of a volume, so that thermoelectric efficiency can be improved.

FIG. 5 illustrates a conceptual view of a heat conversion device according to the other embodiment of the present invention. In particular, in the structure of FIG. 5, the thermoelectric module Z of FIG. 3 including the first semiconductor element 120 and the second semiconductor element 130 is disposed, and the heat conversion substrates 110A, 110B of the heat conversion modules X, Y in direct contact with the first semiconductor element 120 and the second semiconductor element 130 are disposed. In light of this face, the structure is identical to that of the heat conversion device according to the one embodiment of the present invention. However, the structure is different from that of the heat conversion device according to the one embodiment of the present invention, in that separate heat conversion members 220, 320 for implementing and increasing a heat emitting ability and a heat absorbing ability are included.

According to a heat emitting function and a heat absorbing function of the thermoelectric module Z located in a center portion, a fluid (water or air) passing through the heat conversion modules X, Y comes into contact with the heat conversion members 220, 320, so that the heat conversion members 220, 320 according to the present embodiment can enable a heat emitting function and a heat absorbing function to be maximized.

FIG. 6 illustrates one example showing a structure of the heat conversion member 220 included in the heat conversion module according to the other embodiment. FIG. 9 is an enlarged conceptual view showing a structure formed by one flow path pattern 220A included in the heat conversion member 220.

As illustrated, the heat conversion member 220 may be formed in a structure in which at least one flow path pattern 220A forming an air flow path C1 corresponding to the moving path of air is implemented on a substrate having a flat plate-like shape and including a first plane 221 and a second plane 222 opposite to the first plane 221 so that a surface contact with air can be performed.

As illustrated in FIG. 6, the flow path pattern 220A may be implemented in such a manner that the substrate is formed in a folding structure so that curvature patterns having fixed pitches P1, P2 and a fixed height T1 can be formed.

That is, the heat conversion members 220, 320 according to the present embodiment of the invention may be implemented in the structure in which the flow path pattern having two planes in surface contact with the air and for maximizing a surface area in contact with the air is formed.

In the structure illustrated in FIG. 6, when the air flows from a direction of the air flow path C1 of an inflowing part into which the air flows, the air uniformly comes into contact with the first plane 221 and the second plane 222 opposite to the first plane so as to travel to an end direction C2 of the air flow path. Thus, such a structure may realize a higher contact area with the air than a contact surface in the same space so that a heat emitting effect or a heat absorbing effect can be further improved.

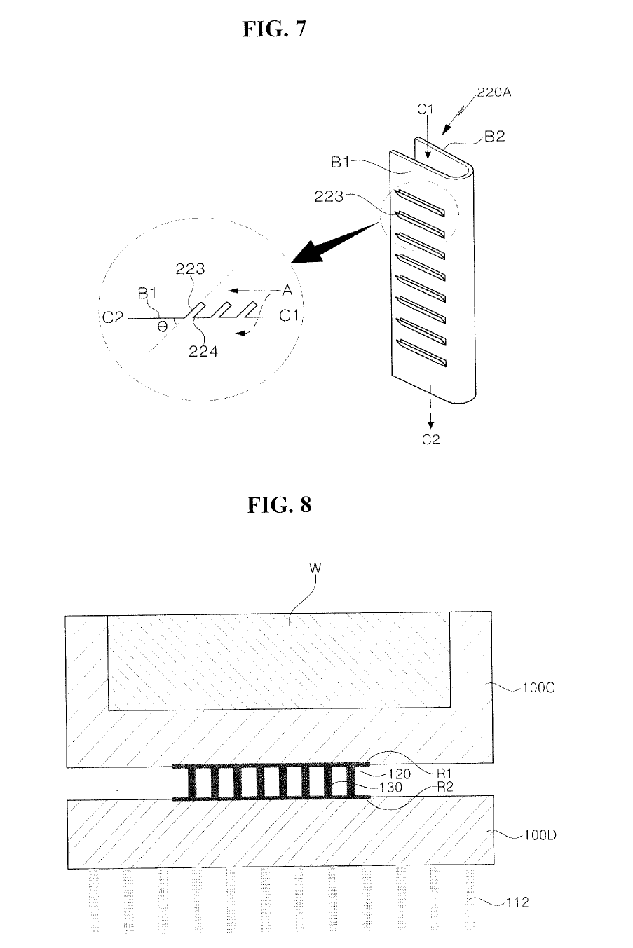

In particular, in order to improve a contact area with the air, the heat conversion member 220 according to the present embodiment of the invention may include resistance patterns 223 on a surface of the substrate as illustrated in FIGS. 6 and 7.

In consideration of the unit flow path patterns, the resistance patterns 223 may be formed on a first curved surface B1 and a second curved surface B2. The resistance patterns may be implemented to protrude in any one direction of a direction of the first plane and a direction of the second plane opposite to the first plane.

Furthermore, the heat conversion member 220 may further include a plurality of fluid flowing grooves 224 passing through the substrate. Thanks to the fluid flowing grooves, a contact with the air and movement of the air may be more freely realized between the first plane and the second plane of the heat conversion member 220.

In particular, as shown in the partially enlarged view of FIG. 7, the resistance patterns 223 are formed as protruding structures inclined to have an inclination angle θ in a direction into which the air is entered so that friction with the air can be maximized, thereby enabling an increase of a contact area or contact efficiency.

The inclination angle θ may be configured so that a horizontal extension line of the surface of the resistance patterns and an extension line of the surface of the substrate make an acute angle. This is because a resistance effect is reduced when the angle is a right angle or an obtuse angle. Moreover, the fluid flowing grooves 224 are disposed at a connection portion between the resistance patterns and the substrate so that resistance to a fluid such as air and the like can be increased, and the movement of air to an opposite surface can be efficiently performed.

Specifically, as the fluid flowing grooves 224 are formed on the surface of the substrate at the front of the resistance patterns 223, the air in connect with the resistance patterns 223 partially pass through a front surface and a rear surface of the substrate so that a contact frequency or a contact area can be increased.

FIG. 8 illustrates an application example of the heat conversion device according to the present invention.

The present invention is intended to increase the efficiency of temperature control by directly forming the electrode patterns on the surface of a device for which heating or cooling is required, and by bringing the thermoelectric semiconductor elements in direct contact with the electrode patterns, rather than by a structure in which the heat conversion device using the thermoelectric module is configured such that the thermoelectric semiconductor elements in the thermoelectric module are disposed between separate substrates.

Accordingly, in the application example, the heat conversion device according to embodiments having various structures may be applied. Furthermore, as shown in FIG. 8, electrode pattern region R1 is implemented on an external surface 100C of a target device for which the cooling or heating of water or a fluid W is required, and the thermoelectric semiconductor elements 120, 130 come into direct contact with the electrode pattern region so that heat transmission efficiency can be increased, and heat loss due to a heterojunction material such as an adhesive material on a contact surface can be prevented.

This application example is not limited to the structure described above. The heat conversion device may be also applied to all temperature control devices using thermoelectric elements. For example, the heat conversion device may be also applied to various devices such as a heat sink structure, a heat pipe, a water storage tank, a wet pit, cold and hot water dispensers, and the like.

According to some embodiments of the present invention, the heat conversion device is configures such that the thermoelectric semiconductor element constituting the thermoelectric module comes into direct contact with the heat conversion substrate of the heat conversion module so that a substrate member constituting the thermoelectric module can be removed and an interface adhesive layer between the substrate member and the heat conversion substrate can be removed. Thus, the heat loss generated between the heterojunction materials due to presence of the adhesive material layer intended for contact of the substrate member and the heat conversion substrate can be prevented, and performance of the thermoelectric elements can be improved.

In particular, in addition to the improvement in the performance of the thermoelectric elements, according to some embodiment of the present invention, the heat conversion member in surface contact with the air is disposed as a radiating structure disposed on a thermoelectric substrate, and the heat conversion member is implemented in the folding structure so that the plurality of flow paths can be formed so that a contact area with the air can be maximized, and heat conversion efficiency can be maximized. Also, thanks to the heat conversion member having the folding structure, a heat conversion device having high efficiency may be also implemented in a limited area of the heat conversion device. As a volume of the product itself is thinly formed, a design arrangement for extensive use can be implemented.

Thanks of the structure of the heat conversion member according to some embodiments of the present invention, the effect of a temperature increase of the heat emitting part and the effect of a temperature reduction of the heat absorbing part can be maximized. In addition, thanks to the folding structure, a thickness of the product itself can be reduced because a volume of the heat conversion member made of aluminum and the like is reduced up to 50% or more compared to a space having the same volume.

As previously described, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents.

What is claimed is:

1. A heat conversion device, comprising:
a unit thermoelectric module including a first semiconductor element and a second semiconductor element; and
a heat conversion module performing heat conversion by coming into contact with the unit thermoelectric module,
wherein the heat conversion module comprises: a heat conversion substrate coming into direct contact with at least any one of one end and the other end of the first semiconductor element or the second semiconductor element; and a radiating unit disposed on the heat conversion substrate.

2. The heat conversion device of claim 1, wherein the heat conversion module comprises an electrode pattern provided on one surface of the heat conversion substrate and electrically connected to first semiconductor element and second semiconductor element.

3. The heat conversion device of claim 2, wherein a thickness of the electrode patterns ranges from 0.01 to 0.3 mm.

4. The heat conversion device of claim 3, wherein the electrode pattern is disposed to be partially buried from a surface of the heat conversion substrate.

5. The heat conversion device of claim 2, further comprising an insulating layer disposed between the electrode pattern and one surface of the heat conversion substrate.

6. The heat conversion device of claim 4, wherein a thickness of the insulating layer ranges from 0.01 to 0.15 mm.

7. The heat conversion device of claim 2, wherein the first semiconductor element is a P-type semiconductor element, and the second semiconductor is an N-type semiconductor element.

8. The heat conversion device of claim 7, wherein a volume of the first semiconductor element and a volume of the second semiconductor element are different from each other.

9. The heat conversion device of claim 8, wherein the volume of the second semiconductor element is larger than the volume of the first semiconductor element.

10. The heat conversion device of claim 7, further comprising a metal solder layer between the first and second semiconductor elements and the electrode pattern.

11. The heat conversion device of claim 2, wherein the radiating unit comprises a plurality of radiating structures in a protruding pin type on the heat conversion substrate.

12. The heat conversion device of claim 2, wherein the radiating unit comprises at least one heat conversion member disposed on the heat conversion substrate and coming into contact with a surface of the heat conversion substrate, the heat conversion member having at least one flow path pattern on a surface of the substrate.

13. The heat conversion device of claim 12, wherein the flow path pattern is implemented in a curvature structure having a pitch in a lengthwise direction of the substrate.

14. The heat conversion device of claim 13, wherein the heat conversion member further comprises a resistance pattern formed on a surface of the flow path pattern and protruding from the surface of the radiating substrate.

15. The heat conversion device of claim 14, wherein the resistance pattern is a protruding structure in which a horizontal extension line of a surface of the resistance pattern and an extension line of the surface of the radiating substrate are inclined to make an inclination angle (θ).

16. The heat conversion device of claim 15, wherein the inclination angle (θ) is an acute angle.

17. The heat conversion device of claim 14, further comprising a plurality of fluid flowing grooves passing through the surface of the radiating substrate.

18. The heat conversion device of claim 17, wherein the fluid flowing grooves are formed in a connection portion between an end of the resistance pattern and the radiating substrate.

19. The heat conversion device of claim 2, further comprising at least two unit thermoelectric modules.
